(19) United States
(12) Patent Application Publication
(10) Pub. No.: US 2024/0088334 A1
(43) Pub. Date: Mar. 14, 2024

(54) OPTICAL COUPLER

(71) Applicant: KAISTAR Lighting (Xiamen) Co., Ltd, Xiamen (CN)

(72) Inventor: Guoheng Qin, Xiamen (CN)

(21) Appl. No.: 18/513,660

(22) Filed: Nov. 20, 2023

Related U.S. Application Data
(63) Continuation of application No. PCT/CN2022/073195, filed on Jan. 21, 2022.

(51) Int. Cl. H01L 33/58; H01L 25/16; H01L 31/0232

(52) U.S. Cl. CPC H01L 33/58; H01L 25/167; H01L 31/02325; H01L 33/32

(57) ABSTRACT

An optical coupler includes: a signal input unit including a first metal bracket and a gallium nitride (GaN)-based light-emitting diode chip disposed thereon, the GaN-based light-emitting diode chip acting as an optical signal emitter and electrically connected to the first metal bracket; a signal output unit including a second metal bracket and a photosensitive device chip disposed thereon, the photosensitive device chip acting as an optical signal receiving and current converter and electrically connected to the second metal bracket; an inner package covering the GaN-based light-emitting diode chip and the photosensitive device chip and forming an optical transmission path between the GaN-based light-emitting diode chip and the photosensitive device chip; and an outer package covering the inner package, the GaN-based light-emitting diode chip and the photosensitive device chip, and partially covering the first metal bracket and the second metal bracket to expose pins of the first and second metal brackets.

### TECHNICAL FIELD

The disclosure relates to the field of photoelectric technologies, and more particularly to an optical coupler.

### BACKGROUND

Optical couplers have a good isolation effect on input and output electrical signals in various circuits. Traditional optical couplers use infrared (IR) light-emitting diodes as emitters, and use photosensitive devices such as diodes, triodes, photoresistors or photothyristors as optical signal receivers and current converters. Due to the maximum response efficiency of the photosensitive devices such as triodes to infrared wavelength light and the advantages of mature products, low price, good low-temperature performance, and low noise of the infrared light-emitting diodes based on gallium arsenide (GaAs) material system, they still have a dominant position in the optical couplers. However, the infrared light-emitting diodes of the GaAs material system are no longer able to meet current needs of circuit applications in the high-temperature field due to the poor temperature resistance of the material itself. In order to overcome limitations of application conditions of the traditional optical couplers, it is necessary to provide a high-temperature resistant high-performance optical coupler.

### SUMMARY

In view of this, embodiments of the disclosure provide an optical coupler that has a better high-temperature resistance performance.

Specifically, an embodiment of the disclosure provides an optical coupler, including a signal input unit, a signal output unit, an inner package, and an outer package. The signal input unit includes a first metal bracket and a gallium nitride (GaN)-based light-emitting diode chip disposed on the first metal bracket, the GaN-based light-emitting diode chip acts as an optical signal emitter and is electrically connected to the first metal bracket. The signal output unit includes a second metal bracket and a photosensitive device chip disposed on the second metal bracket, the photosensitive device chip acts as an optical signal receiving and current converter and is electrically connected to the second metal bracket. The inner package covers the GaN-based light-emitting diode chip and the photosensitive device chip, the inner package forms a light transmission path located between the GaN-based light-emitting diode chip and the photosensitive device chip. The outer package covers the inner package, the GaN-based light-emitting diode chip, and the photosensitive device chip, and partially covers the first metal bracket and the second metal bracket to expose pins of the first metal bracket and pins of the second metal bracket.

In an embodiment of the disclosure, an emission wavelength of the GaN-based light-emitting diode chip is greater than or equal to 420 nanometers (nm) and less than or equal to 500 nm.

In an embodiment of the disclosure, the emission wavelength of the GaN-based light-emitting diode chip is greater than or equal to 420 nm and less than 447.5 nm, or greater than 460 nm and less than or equal to 500 nm.

In an embodiment of the disclosure, a Shore hardness D of the inner package is greater than 50, and a light transmittance of the inner package is greater than 50%.

In an embodiment of the disclosure, the GaN-based light-emitting diode chip includes an indium gallium nitride (InGaN)/GaN multiple quantum well structure (e.g., multiple InGaN layers and multiple GaN layers are alternately stacked), and an indium doping concentration in an InGaN layer of the InGaN/GaN multiple quantum well structure is greater than or equal to 7.8% and less than or equal to 23.6%.

In an embodiment of the disclosure, a wall-plug efficiency (WPE) of the GaN-based light-emitting diode chip is greater than 40% at an input current in a range of 1 milliampere (mA) to 150 mA.

In an embodiment of the disclosure, a current transfer ratio (CTR) of the optical coupler at an operating temperature of 150 Celsius degrees (° C.) is maintained at 60% or more that of at 25° C.

In an embodiment of the disclosure, the signal input unit includes a first light transmission protective layer, and the first light transmission protective layer covers the GaN-based light-emitting diode chip. The signal output unit includes a second light transmission protective layer, and the second light transmission protective layer covers the photosensitive device chip. The inner package covers the first light transmission protective layer and the second light transmission protective layer, and is partially located between the first light transmission protective layer and the second light transmission protective layer. The outer package further covers the first light transmission protective layer and the second light transmission protective layer.

In an embodiment of the disclosure, a refractive index of the first light transmission protective layer is less than or equal to a refractive index of the inner package, and the refractive index of the inner package is less than or equal to a refractive index of the second light transmission protective layer.

In an embodiment of the disclosure, a hardness of the inner package is greater than a hardness of the first light transmission protective layer and a hardness of the second light transmission protective layer, and a Shore hardness A of the first light transmission protective layer and a Shore hardness A of the second light transmission protective layer are less than 60.

In an embodiment of the disclosure, the signal input unit includes a first light transmission protective layer, and the first light transmission protective layer covers the GaN-based light-emitting diode chip. The inner package covers the first light transmission protective layer and is in contact with the photosensitive device chip, and is partially located between the first light transmission protective layer and the photosensitive device chip. The outer package further covers the first light transmission protective layer.

In an embodiment of the disclosure, a refractive index of the first light transmission protective layer is less than or equal to a refractive index of the inner package, a hardness of the inner package is greater than a hardness of the first light transmission protective layer, a Shore hardness A of the first light transmission protective layer is less than 60, and a Shore hardness D of the inner package is greater than 50.

In an embodiment of the disclosure, the inner package is in contact with the GaN-based light-emitting diode chip and the photosensitive device chip individually.

In an embodiment of the disclosure, materials of the inner package include thixotropic light-transmitting resin.

In an embodiment of the disclosure, a height of the inner package is greater than a maximum radial width and less than twice the maximum radial width.

In an embodiment of the disclosure, a Shore hardness D of the inner package is greater than 50 and less than 80.

In addition, another embodiment of the disclosure provides an optical coupler, which includes a signal input unit, a signal output unit, a light-transmitting inner package, and a black outer package. The signal input unit includes a light-emitting diode chip, the light-emitting diode chip acts as an optical signal emitter and the light-emitting diode chip has an emission wavelength greater than or equal to 420 nm and less than 447.5 nm, or greater than 460 nm and less than or equal to 500 nm. The signal output unit includes a photosensitive device chip, the photosensitive device chip acts as a light signal receiving and current converter and is disposed in a face-to-face manner with the light-emitting diode chip. The light-transmitting inner package is configured (i.e., structured and arranged) to form a light transmission path between the light-emitting diode chip and the photosensitive device chip, and the light-transmitting inner package has a light transmittance greater than 50% and a Shore hardness D greater than 50. The black outer package is configured to prevent external light from interfering with an optical signal inside the optical coupler.

In an embodiment of the disclosure, materials of the light-transmitting inner package include thixotropic light-transmitting resin, and the black outer package covers the light-emitting diode chip, the photosensitive device chip and the light-transmitting inner package.

In an embodiment of the disclosure, the signal input unit includes a first metal bracket, the light-emitting diode chip is disposed on the first metal bracket and electrically connected to the first metal bracket. The signal output unit includes a second metal bracket, the photosensitive device chip is disposed on the second metal bracket and electrically connected to the second metal bracket. The light-transmitting inner package is a molded product and covers the light-emitting diode chip and the photosensitive device chip. The black outer package covers the light-emitting diode chip, the photosensitive device chip, and the light-transmitting inner package, and partially covers the first metal bracket and the second metal bracket to expose pins of the first metal bracket and pins of the second metal bracket.

In an embodiment of the disclosure, the light-emitting diode chip is a GaN-based light-emitting diode chip and has a WPE greater than 40% at an input current in a range of 1 mA to 150 mA.

As can be seen from the above, the embodiments of the disclosure use the GaN-based light-emitting diode chip with better high-temperature resistance than the infrared light-emitting diode chip as the optical signal emitter of the signal input unit in the optical coupler, and use the photosensitive device chip as the optical signal receiving and current converter of the signal output unit, combined with the design of the inner and outer packages, which can achieve the increase in the operating temperature of the optical coupler to 150° C. In addition, by selecting the GaN-based light-emitting diode chip of 420 nm-447.5 nm or 460 nm-500 nm that belong to useless stocks in the lighting field, it can balance cost and efficiency to achieve a high-performance optical coupler. Moreover, by using the thixotropic light-transmitting resin to make the inner package, it can simplify the production process and avoid the loss of optical signal caused by the difference of refractive index of various materials. Furthermore, the use of the black outer package can effectively prevent the external light from interfering with the optical signal inside the optical coupler, thereby improving the sensitivity of the optical coupler.

### BRIEF DESCRIPTION OF DRAWINGS

In order to illustrate technical solutions of embodiments of the disclosure more clearly, a brief introduction will be given to the accompanying drawings required in the description of the embodiments. Apparently, the accompanying drawings in the following description are merely some embodiments of the disclosure. For those skilled in the art, other accompanying drawings can be obtained based on these drawings without any creative effort.

FIG. 1 illustrates a partial cross-sectional view of an optical coupler according to a first embodiment of the disclosure.

FIG. 2 illustrates a schematic structural diagram of a metal bracket of a signal input unit of the optical coupler illustrated in FIG. 1.

FIG. 3 illustrates a cross-sectional view of a sapphire based gallium nitride (GaN)-based light-emitting diode (LED) chip according to an embodiment of the disclosure.

FIG. 4 illustrates a cross-sectional view of a silicon based GaN-based LED according to an embodiment of the disclosure.

FIG. 5 illustrates a schematic structural diagram of a metal bracket of a signal output unit of the optical coupler illustrated in FIG. 1.

FIG. 6 illustrates an equivalent circuit diagram of the optical coupler illustrated in FIG. 1.

FIG. 7A illustrates a comparison diagram of current transfer ratio (CTR) between the optical coupler and a traditional optical coupler in the embodiment of the disclosure.

FIG. 7B illustrates a temperature dependent curve of the current conversion rate between the optical coupler and the traditional optical coupler in the embodiment of the disclosure.

FIG. 8A illustrates a partial cross-sectional view of an optical coupler according to a second embodiment of the disclosure.

FIG. 8B illustrates a partial cross-sectional view of an optical coupler according to a third embodiment of the disclosure.

FIG. 9 illustrates a partial cross-sectional view of an optical coupler according to a fourth embodiment of the disclosure.

FIG. 10 illustrates a schematic diagram of a state where an uncured high-arc protective layer is formed on a signal input unit before formation of an internal package of the optical coupler in the fourth embodiment of the disclosure.

FIG. 11 illustrates a schematic diagram of a state where an uncured high-arc protective layer is formed on a signal output unit before formation of an internal package of the optical coupler in the fourth embodiment of the disclosure.

FIGS. 12A and 12B illustrate internal packages with different shapes in other embodiments of the disclosure.

### DETAILED DESCRIPTION OF EMBODIMENTS

In order to make purposes, technical solutions, and advantages of embodiments of the disclosure more clearly, the following will provide a clear and complete description of the technical solutions in the embodiments of the disclosure in conjunction with the accompanying drawings. Apparently, the illustrated embodiments are merely part of the embodiments of the disclosure, not all of them. Based on the embodiments illustrated in the disclosure, all other embodiments obtained by those skilled in the art without creative labor belong to the scope of protection of the disclosure.

It should be noted that all directional indications (such as up, down, left, right, front, rear . . . ) in the embodiments of the disclosure are only used to explain the relative position relationship, motion situation, etc. between components in a specific posture (as illustrated in the accompanying drawings). If the specific posture changes, the directional indication also changes accordingly.

In the embodiments of the disclosure, descriptions such as “first”, “second”, etc. are merely used for descriptive purposes and cannot be construed as indicating or implying their relative importance or implying the number of indicated technical features. Therefore, the features limited to “first” and “second” can explicitly or implicitly include at least one of these features.

Gallium nitride (GaN) material system has the characteristics of high temperature resistance and good thermal stability, but the process of producing GaN-based light-emitting diodes (LEDs) requires the growth of more layers, more defects are formed in the growth process of GaN, and the quality of the defects is usually difficult to control, so that the crystal quality fluctuates greatly and the cost is high. In addition, the response efficiency of photosensitive elements such as triodes commonly used in the optical couplers to GaN-based LEDs in the wavelength range of 365 nanometers (nm) to 600 nm is not as high as that of gallium arsenide (GaAs)-based LEDs, which makes applications of the GaN-based LEDs in the field of the optical couplers have not been promoted.

The inventor of the disclosure has made a lot of exploration and experiments, for example, making GaN-based LED chips containing indium gallium nitride/gallium nitride (InGaN/GaN) multiple quantum well (MQW) structures, by controlling the doping concentration of indium (In) between 7.8% and 23.6%, the GaN-based LED with an emission wavelength ranging from 420 nm to 500 nm under a driving voltage of 2.6 voltages (V) to 3.3 V is selected as an emitter to be applied to the optical coupler of the embodiment of the disclosure. In the wavelength range, the GaN-based LED chip has relatively stable crystal defect quality, good thermal stability, high photoelectric conversion efficiency and high response frequency. With the combination of the photosensitive device chip with good temperature resistance performance and the package, a high temperature resistant optical coupler can be designed and manufactured, which can achieve the operating temperature of the optical coupler to 150° C.

### First Embodiment

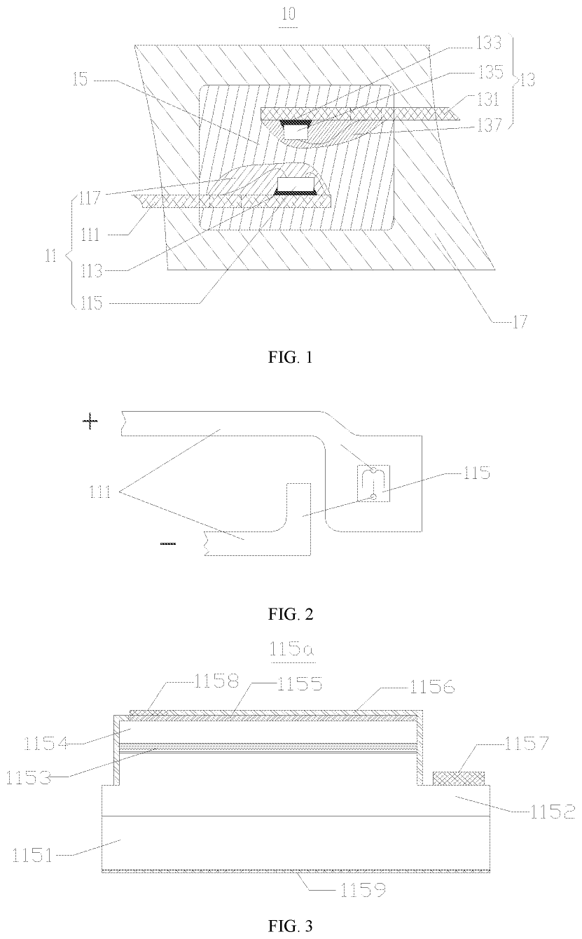

As illustrated in FIG. 1, the first embodiment of the disclosure provides an optical coupler 10, which includes a signal input unit 11, a signal output unit 13, an inner package 15, and an outer package 17.

Specifically, as illustrated in FIG. 1 and FIG. 2, the signal input unit 11 includes a metal bracket 111, a die attach adhesive 113 (also referred to as fixed crystal adhesive), a GaN-based LED chip 115, and a light transmission protective layer 117.

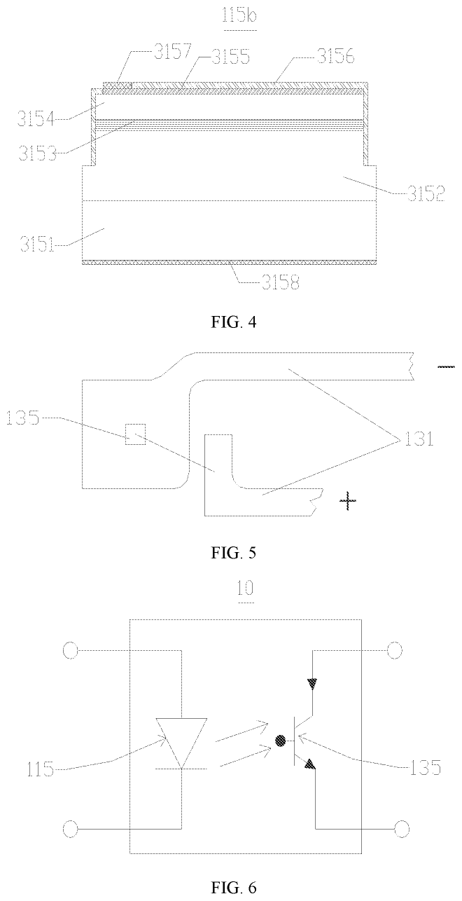

The metal bracket 111 includes a first electrode such as a positive electrode (+) and a second electrode such as a negative electrode (−). The GaN-based LED chip 115, acting as a emitter, is disposed on the positive electrode (+) of the metal bracket 111 through the die attach adhesive 113, and is electrically connected to the positive electrode (+) and the negative electrode (−). The GaN-based LED chip 115 is, for example, a sapphire based GaN-based LED chip 115a illustrated in FIG. 3, or a silicon based GaN-based LED chip 115b illustrated in FIG. 4, but the embodiments of the disclosure are not limited to this.

As illustrated in FIG. 3, the sapphire based GaN-based LED chip 115a includes: a sapphire substrate 1151, a N-type GaN layer 1152, a GaN-based emitting layer 1153, a P-type GaN layer 1154, a transparent contact layer 1155, a dielectric layer 1156, a N-side electrode 1157, a P-side electrode 1158, and a reflective layer 1159. The N-type GaN layer 1152, the GaN-based emitting layer 1153, and the P-type GaN layer 1154 are sequentially stacked on the sapphire substrate 1151, and the GaN-based emitting layer 1153 is, for example, an InGaN/GaN multiple quantum well (MQW) structure. The transparent contact layer 1155 is disposed on a side of the P-type GaN layer 1154 away from the GaN-based emitting layer 1153 and may be an indium tin oxide (ITO) layer. The P-side electrode 1158 is disposed on a side of the transparent contact layer 1155 away from the P-type GaN layer 1154 to form an electrical connection with the P-type GaN layer 1154 through the transparent contact layer 1155. The dielectric layer 1156 is disposed on an upper surface of the transparent contact layer 1155 that is not covered by the P-side electrode 1158, an upper surface of the P-type GaN layer 1154 that is not covered by the transparent contact layer 1155, side surfaces of the P-type GaN layer 1154 and the GaN-based emitting layer 1153, and a partial surface of the N-type GaN layer 1152. The N-side electrode 1157 is disposed on a stepped surface of the N-type GaN layer 1152 to form an electrical connection with the N-type GaN layer 1152. The reflective layer 1159 is disposed on a side of the sapphire substrate 1151 away from the N-type GaN layer 1152. In addition, from FIG. 3, it can be seen that the sapphire based GaN-based LED chip 115a is a lateral type LED chip, so that its N-side electrode 1157 and P-side electrode 1158 can be electrically connected to the negative electrode (−) and the positive electrode (+) of the metal bracket 111 through wiring (as illustrated in FIG. 2).

As illustrated in FIG. 4, the silicon based GaN-based LED chip 115b includes: a silicon substrate 3151, a P-type GaN layer 3152, a GaN-based emitting layer 3153, a N-type GaN layer 3154, a transparent contact layer 3155, a dielectric layer 3156, a N-side electrode 3157, and a P-side electrode 3158. The P-type GaN layer 3152, the GaN-based emitting layer 3153, and the N-type GaN layer 3154 are sequentially stacked on the silicon substrate 3151, and the GaN-based emitting layer 3153 is, for example, an InGaN/GaN multiple quantum well structure. The transparent contact layer 3155 is disposed on a side of the N-type GaN layer 3154 away from the GaN-based emitting layer 3153 and may be an ITO layer. The N-side electrode 3157 is disposed on a side of the transparent contact layer 3155 away from the N-type GaN layer 3154 to form an electrical connection with the N-type GaN layer 3154 through the transparent contact layer 3155. The dielectric layer 3156 is disposed on a portion of an upper surface of the transparent contact layer 3155 that is not covered by the N-side electrode 3157, a portion of an upper surface of the N-type GaN layer 3154 that is not covered by the transparent contact layer 3155, side surfaces of the N-type GaN layer 3154 and the GaN-based emitting layer 3153, and a portion of a side surface of the P-type GaN layer 3152. The P-side electrode 3158 is disposed on a side of the silicon substrate 3151 away from the P-type GaN layer 3152 to form an electrical connection with the P-type GaN layer 3152 through the silicon substrate 3151. In addition, from FIG. 4, it can be seen that the silicon based GaN-based LED chip 115b is a vertical type LED chip, so that its N-side electrode 3157 can be electrically connected to the negative electrode (−) of the metal bracket 111 through wiring, and its P-side electrode 3158 can be electrically connected to the positive electrode (+) of the metal bracket 111 through the die attach adhesive 113.

It is worth noting that the aforementioned sapphire based GaN-based LED chip 115a or the silicon based GaN-based LED chip 115b are both GaN-based LED diode chips with InGaN/GaN multiple quantum well (MQW) structures. The doping concentration of In in the InGaN layer is between 7.8% to 23.6%, and the GaN-based LED chip 115 with an emission wavelength in a range of 420 nm to 500 nm under a driving voltage of 2.6 V to 3.3 V is selected. In an embodiment, a GaN-based LED chip with an emission wavelength in a range of 440 nm to 480 nm is selected, and the chip within this main wavelength range has the best emission efficiency. In addition, in order to make up for the shortage of the response efficiency of the photosensitive device chip 135 to the light of this band, the GaN-based LED chip with a wall-plug efficiency (WPE) greater than 40% at an input current in a range of 1 milliampere (mA) to 150 mA can be selected, and/or the GaN-based LED chip with a light area relatively larger than infrared LED chips with the same response efficiency can be selected.

In addition, as illustrated in FIG. 1, the light transmission protective layer 117 is fabricated on the GaN-based LED chip 115 and metal wires. The light transmission protective layer 117 of the embodiment adopts a light-transmitting resin material, which includes high-temperature resistant resin materials such as silicone resin, epoxy resin, or modified resin.

Based on the requirements and selection of the thermal flexibility of the material, it can be reflected that the Shore hardness A after curing is less than 60. In an embodiment, for the signal input unit 11, a die attach area of the metal bracket 111 is subjected to surface roughness treatment, with a surface roughness controlled at 0.1 micrometers (μm) to 1 μm to increase the binding force of the light transmission protective layer 117 and reduce light reflection to reduce signal interference.

As illustrated in FIG. 1 and FIG. 5, the signal output unit 13 includes a metal bracket 131, a die attach adhesive 133, a photosensitive device chip 135, and a light transmission protective layer 137. Specifically, the metal bracket 131 includes a first electrode such as a positive electrode (+) and a second electrode such as a negative electrode (−). The photosensitive device chip 135 is disposed on the negative electrode (−) of the metal bracket 131 through the die attach adhesive 133 to be electrically connected the negative electrode (−) through the die attach adhesive 133, and is electrically connected the positive electrode (+) of the metal bracket 131 through wiring. In addition, the photosensitive device chip 135 is used as an optical signal receiving and current converter, such as a diode, a triode, a photoresistor or a photoelectric thyristor. In this embodiment, the silicon based NPN-type triode (i.e., a triode composed of two N-type semiconductors sandwiched between a P-type semiconductor) is used as an example of the photosensitive device chip 135. Moreover, the light transmission protective layer 137 is fabricated on the photosensitive device chip 135 and metal wires, the light transmission protective layer 137 adopts a light-transmitting resin material, for example, and the light-transmitting resin material includes high-temperature resistant resin materials such as silicone resin, epoxy resin, or modified resin. Based on the requirements and selection of the thermal flexibility of the material, it can be reflected that the Shore hardness A after curing is less than 60. In an embodiment, for the signal output unit 13, a die attach area of the metal bracket 131 is subjected to surface roughness treatment, with a surface roughness controlled at 0.1 μm to 1 μm to increase the binding force of the light transmission protective layer 137 and reduce light reflection to reduce signal interference.

As illustrated in FIG. 1, the signal input unit 11 and the signal output unit 13 are arranged in a face-to-face manner, and the light-emitting resin material is filled between the signal input unit 11 and the signal output unit 13 to package and fix to thereby obtain the inner package 15. The light-emitting resin material herein can be silicone resin, epoxy resin, or its modified resin (different groups can affect its hardness and transmittance), etc. The inner package 15 acts as an optical signal transmission medium between the signal input unit 11 and the signal output unit 13 to form an optical transmission path, with a transmittance greater than 50%, preferably greater than or equal to 90%, and more preferably greater than or equal to 95% for the signal light. In addition, based on the requirements and selection for material transparency and moldability, it can be reflected that the Shore hardness D after curing is greater than 50. From FIG. 1, it can be seen that the inner package 15 covers a portion of the metal bracket 111 of the signal input unit 11 to expose the pins, the die attach adhesive 113, the GaN-based LED chip 115, and the light transmission protective layer 117, and covers a portion of the metal bracket 131 of the signal output unit 13 to expose the pins, the die attach adhesive 133, the photosensitive device chip 135, and the light transmission protective layer 137. In an embodiment, in order to reduce light transmission loss, the relationship between the refractive index of the inner package 15, the light transmission protective layer 117, and the light transmission protective layer 137 is that the refractive index of the light transmission protective layer 117 is less than or equal to the refractive index of the inner package 15, and the refractive index of the inner package 15 is less than or equal to the refractive index of the light transmission protective layer 137 to avoid total reflection. Furthermore, the inner package 15 is used to fix the relative position of the signal input unit 11 and the signal output unit 13, which requires higher hardness. Therefore, in an embodiment, the hardness of the inner package 15 is greater than the hardness of the light transmission protective layer 117 and the hardness of the light transmission protective layer 137.

In addition, in order to prevent interference of signals by external light to enhance the sensitivity of the optical coupler 10, the outer package 17 is used to cover the inner package 15 and partially cover the signal input unit 11 and the signal output unit 13 to expose the pins of the metal bracket 111 of the signal input unit 11 and the pins of the metal bracket 131 of the signal output unit 13. In other words, the outer package 17 covers the inner package 15, covers the portion of the metal bracket 111 of the signal input unit 11 to expose the pins, the die attach adhesive 113, the GaN-based LED chip 115 and the light transmission protective layer 117, and covers the portion of the metal bracket 131 of the signal output unit 13 to expose the pins, the die attach adhesive 133, the photosensitive device chip 135, and the light transmission protective layer 137. The outer package 17 herein is, for example, made of black epoxy resin to take advantage of the light-absorbing properties of black to prevent external light from interfering with the signal.

It is worth mentioning that the pins of the metal bracket 111 of the signal input unit 11 and the pins of the metal bracket 131 of the signal output unit 13 may be subjected to surface treatment, such as tin plating, to prevent oxidation. In addition, in the production process of the batch production of the optical coupler 10 of the embodiment, process steps such as pin bending, test sorting and packaging processing are usually performed.

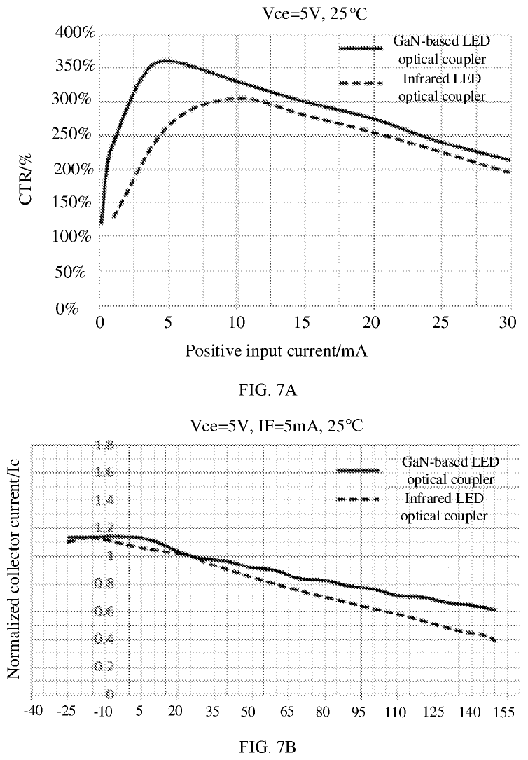

In addition, as illustrated in FIG. 6, FIG. 7A and FIG. 7B, FIG. 6 illustrates an equivalent circuit diagram of the optical coupler 10 of the embodiment, and FIG. 7A and FIG. 7B illustrate key performance comparisons of the optical coupler 10 of the embodiment with a traditional optical coupler. As can be seen from FIG. 7A, in terms of current transfer ratio (CTR), the GaN-based LED chip with an InGaN/GaN multiple quantum well (MQW) structure is adopted in the embodiment, the In doping concentration is selected to be between 7.8% and 23.6%, and the emission wavelength is between 420 nm and 500 nm at a drive voltage in a range of 2.6 V to 3.3 V. In an embodiment, the GaN-based LED chip 115 with WPE greater than 40% at the input current in range of 1 mA to 150 mA is used as the emitter of the optical coupler 10 with a CTR comparable to that of a traditional optical coupler using a GaAs-based infrared LED chip as the emitter. As can be seen from FIG. 7B, in terms of the change of CTR with ambient temperature, when the CTR is reduced to 60% of the normal temperature with the increase of the operating temperature, the corresponding temperature of the optical coupler 10 using the GaN-based LED chip 115 as the emitter in the embodiment can reach 150° C., while the corresponding temperature of the traditional optical coupler using GaAs-based infrared LED chip as the emitter is 110° C. In other words, when the operating temperature of the optical coupler using the GaN-based LED chip 115 as the emitter in the embodiment reaches 150° C., the CRT value of the optical coupler can be maintained at 60% or more of the normal temperature, so that the high temperature resistance of the optical coupler 10 in the embodiment is significantly improved. In addition, in terms of the response frequency, the optical coupler 10 using the GaN-based LED chip 115 as the emitter in the embodiment has a response frequency equivalent to that of the traditional optical coupler using the GaAs-based infrared LED chip as the emitter when the same triode is used as the photosensitive device chip, for example, up to 30 kilohertz (kHz).

Finally, it is worth stating that the wavelength range of the GaN-based LED chip at the driving voltage in a range of 2.6 V to 3.3 V usually available for general lighting is in a range of 447.5 nm to 460 nm, but LEDs chips with wavelengths beyond this range are inevitable in the manufacturing process of the GaN-based LEDs chips, and the LEDs chips with wavelengths between 420 nm to 447.5 nm or 460 nm to 500 nm are useless stocks in the field of lighting. However, they can be fully utilized in the optical coupler 10 of the embodiment, which have very obvious cost advantages and commercial value, especially for the GaN-based LED chip in the wavelength range above 460 nm, the application effect is better. Moreover, through the inventor's experiments, in order to enable the optical coupler 10 adopting the GaN-based LED chip as the emitter to have better CTR compared with the traditional optical coupler adopting the infrared LED chip as the emitter, the GaN-based LED chip with a relatively large size can be selected, so from the aspect of balancing cost, the use of the LEDs chips with wavelengths between 420 nm to 447.5 nm or 460 nm to 500 nm of the useless stocks in the field of lighting can balance the cost and efficiency. In addition, as described above, since the optimal emission wavelength band of the GaN-based LED chip is 440 nm to 480 nm, the LED chip with the emission wavelength in the range of 440 nm to 447.5 nm and 460 nm to 480 nm are selected as the GaN-based LED chip 115 of the optical coupler 10 in the illustrated embodiment of the disclosure. In an embodiment, the LED chip with the emission wavelength in the range of 460 nm to 480 nm as the GaN-based LED chip 115 of the optical coupler 10.

### Second Embodiment

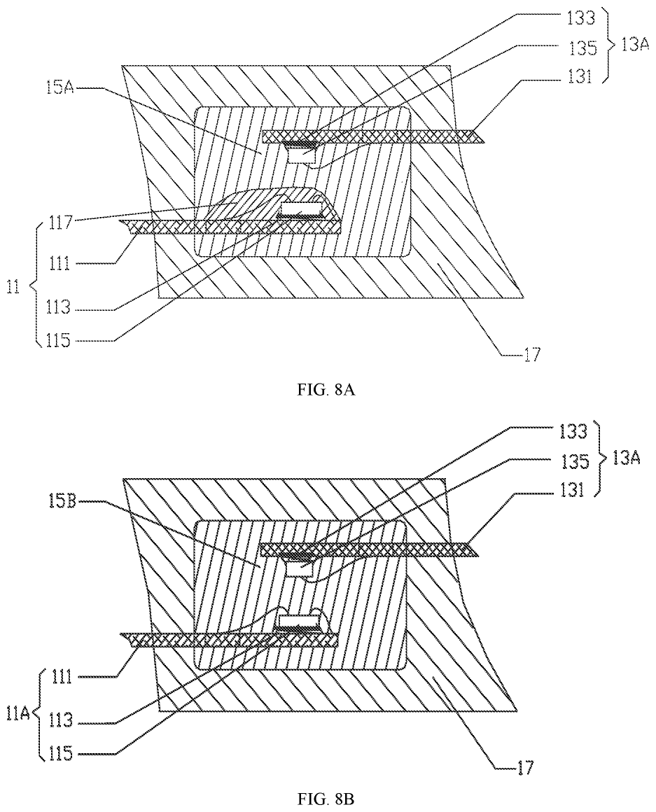

As illustrated in FIG. 8A, the second embodiment of the disclosure provides an optical coupler including: a signal input unit 11, a signal output unit 13A, an inner package 15A and an outer package 17.

Specifically, the signal input unit 11 and the outer package 17 are the same as the signal input unit 11 and outer package 17 in the first embodiment described above, and are not be described herein. The difference between the signal output unit 13A and the signal output unit 13 of the first embodiment is only that the light transmission protective layer 137 is not provided in the signal output unit 13A, and the difference between the inner package 15A and the inner package 15 of the first embodiment is only that the inner package 15A is in direct contact with the photosensitive device chip 135. In addition, it is worth mentioning that in this embodiment, the Shore hardness D of the inner package 15A is greater than 50, and the Shore hardness A of the light transmission protective layer 117 of the signal input unit 11 is less than 60.

In this embodiment, the signal output unit 13A without the light transmission protective layer 137 is used in the optical coupler, which can have substantially the same performance as the optical coupler 10 described in the first embodiment.

### Third Embodiment

As illustrated in FIG. 8B, the third embodiment of the disclosure provides an optical coupler including: a signal input unit 11A, a signal output unit 13A, an inner package 15B, and an outer package 17.

Specifically, the outer package 17 is the same as the outer package 17 in the first embodiment described above, and is not be repeated herein. The difference between the signal input unit 11A and the signal input unit 11 of the first embodiment is only that the light transmission protective layer 117 is not provided in the signal input unit 11A, the difference between the signal output unit 13A and the signal output unit 13 of the first embodiment is only that the light transmission protective layer 137 is not provided in the signal output unit 13A, and the difference between the inner package 15B and the inner package 15 of the first embodiment is only that the inner package 15B is in direct contact with both the GaN-based LED chip 115 and the photosensitive device chip 135. In addition, it is worth mentioning that in this embodiment, the Shore hardness D of the inner package 15B is greater than 50, but in order to prevent the stress from damaging the chip and the gold wire, its Shore hardness D needs to be less than 80.

In this embodiment, the signal input unit 11A without the light transmission protective layer 117 and the signal output unit 13A without the light transmission protective layer 137 are used in the optical coupler, which can have essentially the same performance as the optical coupler 10 described in the first embodiment.

### Fourth Embodiment

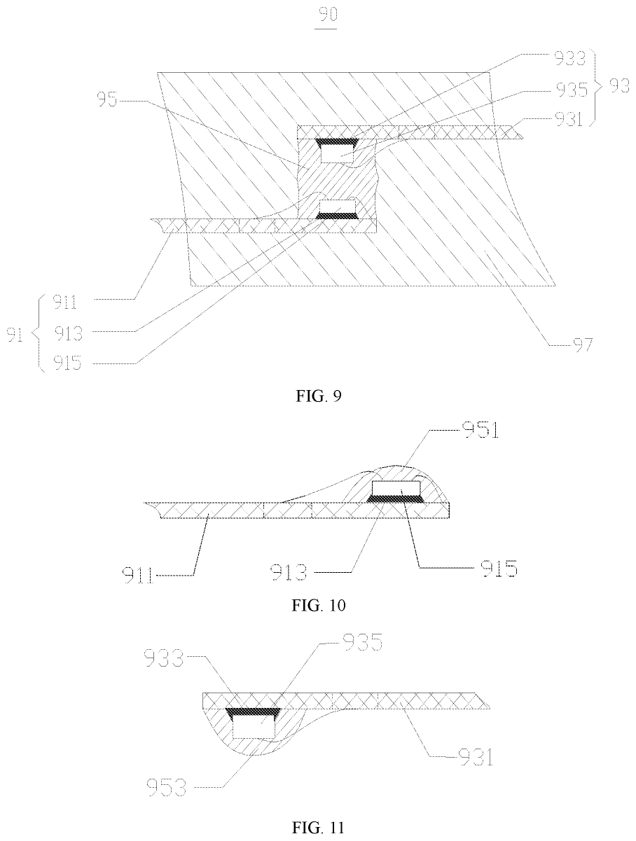

As illustrated in FIG. 9, a fourth embodiment of the disclosure provides an optical coupler 90 including: a signal input unit 91, a signal output unit 93, an inner package 95, and an outer package 97.

Specifically, the signal input unit 91 includes a metal bracket 911, a die attach adhesive 913 and a GaN-based LED chip 915.

In particular, the metal bracket 911 includes a first electrode such as a positive electrode (+) and a second electrode such as a negative electrode (−) (referring to FIG. 2), and the GaN-based LED chip 915 as an emitter is disposed on the positive electrode (+) of the metal bracket 911 through the die attach adhesive 913 and electrically connected to the positive electrode (+) and the negative electrode (−). The GaN-based LED chip 915 is, for example, a sapphire based GaN-based LED chip 115a illustrated in FIG. 3, or a silicon based GaN-based chip 115b illustrated in FIG. 4, but embodiments of the disclosure are not limited to this.

As illustrated in FIG. 10, a high-arc protective layer 951 is self-formed on the GaN-based LED chip 915 and metal wires by using the thixotropic light-transmitting resin, which is not cured yet. The thixotropic light-transmitting resin used in the high-arc protective layer 951 of this embodiment has a thixotropic coefficient of, for example, greater than or equal to 3.5, and contains, for example, a high-temperature resistant resin material such as silicone resin, epoxy resin, or a modified resin thereof. In an embodiment, for the signal input unit 91, the die attach area of the metal bracket 911 is surface roughened with a surface roughness controlled within 0.1 μm to 1 μm, so as to increase the bonding force of the high-arc protective layer 951 and to reduce the reflection of light to thereby reduce signal interference.

As described above, the signal output unit 93 includes a metal bracket 931, a die attach adhesive 933 and a photosensitive device chip 935. Specifically, the metal bracket 931 includes a first electrode such as a positive electrode (+) and a second electrode such as a negative electrode (−) (referring to FIG. 5), and the photosensitive device chip 935 is disposed on the negative electrode (−) of metal bracket 931 by the die attach adhesive 933 to be electrically connected the negative electrode (−) by the die attach adhesive 933, and is electrically connected the positive electrode (+) of the metal bracket 931 through a wire bonding manner. In addition, the photosensitive device chip 935 acts as an optical signal receiving and current converter, which is, for example, a diode, a triode, a photoresistor or a phototransistor, and a silicon based NPN-type triode is used as an example of the photosensitive device chip 935 in this embodiment. As illustrated in FIG. 11, a high-arc protective layer 953 is self-formed on the photosensitive device chip 935 and metal wires by using the thixotropic light-transmitting resin, which is not cured yet. The thixotropic light-transmitting resin used in the high-arc protective layer 953 of this embodiment has a thixotropic coefficient of, for example, greater than or equal to 3.5, and contains, for example, a high temperature resistant resin material such as a silicone resin, an epoxy resin, or a modified resin thereof. In an embodiment, for the signal output unit 93, the die attach area of the metal bracket 931 is surface roughened with a surface roughness controlled within 0.1 μm to 1 μm, so as to increase the bonding force of the high-arc protective layer 953 and to reduce the reflection of light to thereby reduce signal interference.

The signal input unit 91 and the signal output unit 93 are disposed in a face-to-face manner, the high arc protection layers 951 and 953 are self-formed by blending with each other by using the characteristics of the uncured thixotropic resin, and the inner package 95 as an optical signal transmission medium is formed between the signal input unit 91 and the signal output unit 93 after semi-curing to form an optical transmission path, and to allow the signal input unit 91 and the signal output unit 93 be connected and fixed. The inner package 95 has a signal light transmittance of 50%, preferably greater than or equal to 90%, more preferably greater than or equal to 95%. As can be seen from FIG. 9, the inner package 95 covers a portion of the metal bracket 911 of the signal input unit 91 to expose the pins, the die attach adhesive 813 and the GaN-based LED chip 915, and covers a portion of the metal bracket 931 of the signal output unit 93 to expose the pins, the die attach adhesive 933 and the photosensitive device chip 935.

In order to prevent interference of signals by external light to enhance the sensitivity of the optical coupler 90, the outer package 97 is utilized to cover the inner package 95 and partially cover the signal input unit 91 and the signal output unit 93 to expose the pins of the metal bracket 911 of the signal input unit 91 and the pins of the metal bracket 931 of the signal output unit 93. In other words, the outer package 97 covers the inner package 95, covers a portion of the metal bracket 911 of the signal input unit 91 to expose the pins, the die attach adhesive 913 and the GaN-based LED chip 915, and covers a portion of the metal bracket 931 of the signal output unit 93 to expose the pins, the die attach adhesive 933 and the photosensitive device chip 935. The outer package 97 herein is, for example, made of black epoxy resin to take advantage of the light-absorbing properties of black to prevent external light from interfering with the signal.

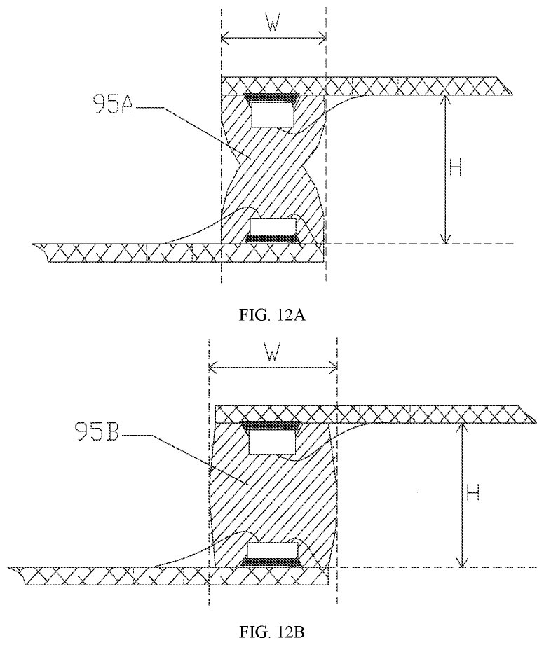

It is worth mentioning that the pins of the metal bracket 911 of the signal input unit 91 and the pins of the metal bracket 931 of the signal output unit 93 may be subjected to surface treatment, such as tin plating, to prevent oxidation. In addition, in the production process of the batch production of the optical coupler 90 of the embodiment, process steps such as pin bending, test sorting and packaging processing are usually performed. As can be seen from FIG. 9, the inner package 95 of this embodiment is shaped as a cylinder with irregular side surfaces, whose height is greater than the maximum radial width and less than twice the maximum radial width. Of course, depending on the degree of thixotropy of the resin material or the amount of adhesive, it can be other shapes, such as those illustrated in FIG. 12A or FIG. 12B. Specifically, in FIG. 12A, the inner package 95A has a hourglass-like shape with wider top and bottom ends and a concave middle, and its height H is greater than the maximum radial width W and less than twice the maximum radial width W, i.e., W<H<2H. In FIG. 12B, the inner package 95B has a drum-like shape with narrow top and bottom ends and a convex middle, and its height H is greater than the maximum radial width W and less than twice the maximum radial width W, and less than twice the maximum radial width W, i.e., W<H<2W.

In addition, referring to FIG. 7A and FIG. 7B, it can be seen from FIG. 7A that in terms of current transfer ratio (CTR), the GaN-based LED chip 95 with an InGaN/GaN multiple quantum well structure is adopted in the embodiment, the In doping concentration is selected to be between 7.8% and 23.6%, and the emission wavelength is between 420 nm and 500 nm at a drive voltage in a range of 2.6 V to 3.3 V. In an embodiment, the GaN-based LED chip 95 with WPE greater than 40% at the input current in range of 1 mA to 150 mA is used as the emitter of the optical coupler 90 with a CTR comparable to that of a traditional optical coupler using a GaAs-based infrared LED chip as the emitter. As can be seen from FIG. 7B, in terms of the change of CTR with ambient temperature, when the CTR is reduced to 60% of the normal temperature with the increase of the operating temperature, the corresponding temperature of the optical coupler 90 using the GaN-based LED chip 95 as the emitter in the embodiment can reach 150° C., while the corresponding temperature of the traditional optical coupler using GaAs-based infrared LED chip as the emitter is 110° C. Thus, it can be seen that the high temperature resistance of the optical coupler 90 in this embodiment is significantly improved. In addition, in terms of the response frequency, the optical coupler 90 using the GaN-based LED chip 95 as the emitter in the embodiment has a response frequency equivalent to that of the traditional optical coupler using the GaAs-based infrared LED chip as the emitter when the same triode is used as the photosensitive device chip, for example, up to 30 kHz.

Finally, the wavelength range of the GaN-based LED chip at the driving voltage in a range of 2.6 V to 3.3 V usually available for general lighting is in a range of 447.5 nm to 460 nm, but LEDs chips with wavelengths beyond this range are inevitable in the manufacturing process of the GaN-based LEDs chips, and the LEDs chips with wavelengths between 420 nm to 447.5 nm or 460 nm to 500 nm are useless stocks in the field of lighting. However, they can be fully utilized in the optical coupler 90 of the embodiment, which have very obvious cost advantages and commercial value, especially for the GaN-based LED chip in the wavelength range above 460 nm, the application effect is better. Moreover, through the inventor's experiments, in order to enable the optical coupler 90 adopting the GaN-based LED chip as the emitter to have better CTR compared with the traditional optical coupler adopting the infrared LED chip as the emitter, the GaN-based LED chip with a relatively large size can be selected, so from the aspect of balancing cost, the use of the LEDs chips with wavelengths between 420 nm to 447.5 nm or 460 nm to 500 nm of the useless stocks in the field of lighting can balance the cost and efficiency. In addition, as described above, since the optimal emission wavelength band of the GaN-based LED chip is 440 nm to 480 nm, the LED chip with the emission wavelength in the range of 440 nm to 447.5 nm and 460 nm to 480 nm are selected as the GaN-based LED chip 95 of the optical coupler 90 in the illustrated embodiment of the disclosure. In an embodiment, the LED chip with the emission wavelength in the range of 460 nm to 480 nm as the GaN-based LED chip 95 of the optical coupler 90.

It should be noted that the fourth embodiment of the disclosure uses thixotropic light-transmitting resin to form the inner package 95, which on the one hand can save the molding process of the inner package 15, 15A, 15B of the first, second and third embodiments mentioned above, and on the other hand can avoid the light energy loss caused by the difference in refractive index of various resin materials.

In addition, it can be understood that the foregoing embodiments are only exemplary descriptions of the disclosure, and the technical solutions of the embodiment can be used in any combination and collocation under the premise that the technical features do not conflict, the structure does not contradict, and the purpose of the disclosure is not violated.

Finally, it should be noted that the above embodiments are only used to illustrate the technical solutions of the disclosure, not to limit them. Although the disclosure is described in detail with reference to the foregoing embodiments, those skilled in the art should understand that the technical solutions described in the foregoing embodiments can still be modified, or some of the technical features thereof can be equivalently substituted. These modifications or substitutions do not make the essence of the corresponding technical solutions deviate from the spirit and scope of the technical solutions of the embodiments of the disclosure.

What is claimed is:

1. An optical coupler, comprising:
a signal input unit, comprising a first metal bracket and a gallium nitride (GaN)-based light-emitting diode chip disposed on the first metal bracket, wherein the GaN-based light-emitting diode chip acts as an optical signal emitter and is electrically connected to the first metal bracket;
a signal output unit, comprising a second metal bracket and a photosensitive device chip disposed on the second metal bracket, wherein the photosensitive device chip acts as an optical signal receiving and current converter and is electrically connected to the second metal bracket;
an inner package, covering the GaN-based light-emitting diode chip and the photosensitive device chip, wherein the inner package forms an optical transmission path located between the GaN-based light-emitting diode chip and the photosensitive device chip; and
an outer package, covering the inner package, the GaN-based light-emitting diode chip and the photosensitive device chip, and partially covering with the first metal bracket and the second metal bracket to expose pins of the first metal bracket and pins of the second metal bracket.

2. The optical coupler as claimed in claim 1, wherein an emission wavelength of the GaN-based light-emitting diode chip is greater than or equal to 420 nanometers (nm) and less than or equal to 500 nm.

3. The optical coupler as claimed in claim 2, wherein the emission wavelength of the GaN-based light-emitting diode chip is greater than or equal to 420 nm and less than 447.5 nm, or greater than 460 nm and less than or equal to 500 nm.

4. The optical coupler as claimed in claim 1, wherein a Shore hardness D of the inner package is greater than 50, and a light transmittance of the inner package is greater than 50%.

5. The optical coupler as claimed in claim 1, wherein the GaN-based light-emitting diode chip comprises an indium gallium nitride (InGaN)/GaN multiple quantum well structure, and an indium doping concentration in an InGaN layer of the InGaN/GaN multiple quantum well structure is greater than or equal to 7.8% and less than or equal to 23.6%.

6. The optical coupler as claimed in claim 1, wherein a wall-plug efficiency (WPE) of the GaN-based light-emitting diode chip is greater than 40% at an input current in a range of 1 milliampere (mA) to 150 mA.

7. The optical coupler as claimed in claim 1, wherein a current transfer ratio (CTR) of the optical coupler at an operating temperature of 150 Celsius degrees (° C.) is maintained at 60% or more that of at 25° C.

8. The optical coupler as claimed in claim 1, wherein the signal input unit comprises a first light transmission protective layer, and the first light transmission protective layer covers the GaN-based light-emitting diode chip; the signal output unit comprises a second light transmission protective layer, and the second light transmission protective layer covers the photosensitive device chip; the inner package covers the first light transmission protective layer and the second light transmission protective layer, and is partially located between the first light transmission protective layer and the second light transmission protective layer; and the outer package further covers the first light transmission protective layer and the second light transmission protective layer.

9. The optical coupler as claimed in claim 8, wherein a refractive index of the first light transmission protective layer is less than or equal to a refractive index of the inner package, and the refractive index of the inner package is less than or equal to a refractive index of the second light transmission protective layer.

10. The optical coupler as claimed in claim 9, wherein a hardness of the inner package is greater than a hardness of the first light transmission protective layer and a hardness of the second light transmission protective layer, and a Shore hardness A of the first light transmission protective layer and a Shore hardness A of the second light transmission protective layer are less than 60.

11. The optical coupler as claimed in claim 1, wherein the signal input unit comprises a first light transmission protective layer, and the first light transmission protective layer covers the GaN-based light-emitting diode chip; the inner package covers the first light transmission protective layer and is in contact with the photosensitive device chip, and is partially located between the first light transmission protective layer and the photosensitive device chip; and the outer package further covers the first light transmission protective layer.

12. The optical coupler as claimed in claim 8, wherein a refractive index of the first light transmission protective layer is less than or equal to a refractive index of the inner package, a hardness of the inner package is greater than a hardness of the first light transmission protective layer, a Shore hardness A of the first light transmission protective layer is less than 60, and a Shore hardness D of the inner package is greater than 50.

13. The optical coupler as claimed in claim 1, wherein the inner package is in contact with the GaN-based light-emitting diode chip and the photosensitive device chip individually.

14. The optical coupler as claimed in claim 1, wherein materials of the inner package comprise thixotropic light-transmitting resin.

15. The optical coupler as claimed in claim 14, wherein a height of the inner package is greater than a maximum radial width and less than twice the maximum radial width.

16. The optical coupler as claimed in claim 13, wherein a Shore hardness D of the inner package is greater than 50 and less than 80.

17. An optical coupler, comprising:
a signal input unit, comprising a light-emitting diode chip, wherein the light-emitting diode chip acts as an optical signal emitter and the light-emitting diode chip has an emission wavelength greater than or equal to 420 nm and less than 447.5 nm, or greater than 460 nm and less than or equal to 500 nm;
a signal output unit, comprising a photosensitive device chip, wherein the photosensitive device chip acts as an optical signal receiving and current converter and is disposed in a face-to-face manner with the light-emitting diode chip;
a light-transmitting inner package, configured to form a light transmission path between the light-emitting diode chip and the photosensitive device chip, wherein the light-transmitting inner package has a light transmittance greater than 50% and a Shore hardness D greater than 50; and
a black outer package, configured to prevent external light from interfering with an optical signal inside the optical coupler.

18. The optical coupler as claimed in claim 17, wherein materials of the light-transmitting inner package comprise thixotropic light-transmitting resin, and the black outer package covers the light-emitting diode chip, the photosensitive device chip and the light-transmitting inner package.

19. The optical coupler as claimed in claim 17, wherein the signal input unit comprises a first metal bracket, the light-emitting diode chip is disposed on the first metal bracket and electrically connected to the first metal bracket; the signal output unit comprises a second metal bracket, the photosensitive device chip is disposed on the second metal bracket and electrically connected to the second metal bracket; the light-transmitting inner package is a molded product and covers the light-emitting diode chip and the photosensitive device chip; the black outer package covers the light-emitting diode chip, the photosensitive device chip and the light-transmitting inner package, and partially covers the first metal bracket and the second metal bracket to thereby expose pins of the first metal bracket and pins of the second metal bracket.

20. The photocoupler as claimed in claim 17, wherein the light-emitting diode chip is a GaN-based light-emitting diode chip and has a WPE greater than 40% at an input current in a range of 1 mA to 150 mA.
